(19) United States
(12) Patent Application Publication
(10) Pub. No.: US 2002/0031711 A1
(43) Pub. Date: Mar. 14, 2002

(54) Multi-level lithography masks

(76) Inventors: Dan A. Steinberg, Blacksburg, VA (US); Mindaugas F. Dautartas, Blacksburg, VA (US); David W. Sherrer, Blacksburg, VA (US)

Correspondence Address: JONES VOLENTINE, L.L.C., SUITE 150, 12200 SUNRISE VALLEY DRIVE, RESTON, VA, 20191, US

(21) Appl. No.: 09/853,250

(22) Filed: May 9, 2001

Related U.S. Application Data
(60) Provisional application No. 60/202,596, filed on May 9, 2000.
(60) Provisional application No. 60/204,473, filed on May 16, 2000.
(60) Provisional application No. 60/257,021, filed on Dec. 20, 2000.

(51) Int. Cl. G03C 5/00; G03F 9/00

(52) U.S. Cl. 430/5; 430/322; 430/22; 430/323; 430/324

(57) ABSTRACT

A lithography multi-level mask includes a base layer with at least one mesa disposed over the base layer. The mesa has a first transmittance and the substrate has a second transmittance. The first transmittance is greater than or equal to the second transmittance.

An image lithography method includes locating a multi-level mask over a substrate. The multi-level mask has at least one mesa which is complementary to a region of the substrate. The method further includes irradiating the multi-level mask with a radiation source to selectively expose a resist layer disposed over the substrate.

A method of forming features on a substrate includes providing a substrate and locating a multi-level mask over the substrate, where the multi-level mask includes at least one valley and at least one substrate. The multi-level mask is irradiated to selectively expose a resist layer disposed over first and second levels of the substrate.

### CROSS-REFERENCE TO RELATED APPLICATIONS

The present invention is related to and claims priority from the following U.S. Provisional Patent Applications: Ser. No. 60/202,596, entitled “Multilevel Contact Mask For Patterning Multilevel Substrates”, filed May 9, 2000; and Ser. No. 60/204,473, entitled “Single Mask Process for Patterning Integrated Optic Waveguides, Metallizations and Micromachined Features,” filed May 16, 2000. The present invention is also related to and claims priority from U.S. Patent Application No. 60/257,021, entitled “Alternative Embodiment For Making The Multilevel Contact mask”, filed Dec. 20, 2000. The disclosures of the above captioned provisional patent applications are specifically incorporated by reference in their entirety and for all purposes.

### FIELD OF THE INVENTION

The present invention relates generally to integrated circuits (IC), optical integrated circuits (OIC) and optical benches. More particularly, the present invention relates to a multi-level mask and its use in image projection lithography.

### BACKGROUND OF THE INVENTION

IC and OIC fabrication often involves transferring patterns to a substrate. These patterns may be used to form a variety of structures to include conductive circuit lines, planar waveguides, mesas and recesses. Typically, the desired structures are formed using lithography. Lithography may be achieved by techniques such as photolithography, x-ray lithography and e-beam lithography.

In photolithography, for example, a layer of photo-reactive film, known as photoresist, may be formed over the substrate. A photolithographic mask containing the image of a desired pattern is then placed in contact with the photoresist film. Radiation of a wavelength to which the photoresist is sensitive is incident upon the mask. The radiation passes through the transparent areas of the mask and the exposed areas of the photoresist are reactive to the radiation. The photoresist film is then chemically developed, leaving behind a pattern of photoresist substantially identical to the pattern on the mask.

The patterned photoresist on the substrate may be used in a variety of applications to form the structures referenced above. For example, a pattern photoresist may act as a mask for selective etching of a substrate. This selective etching may be used to fabricate recesses and as mesas in the substrate. In OIC and optical bench technologies, the mesas and recesses may be used for a variety of purposes, including passive alignment of optical elements.

The above described photolithographic process is often referred to as contact printing, because the mask is placed in contact with the substrate. Contact printing has facilitated the fabrication of highly integrated structures in both electrical and optical integrated circuits. However, conventional contact printing techniques have certain limitations. For example, conventional contact printing techniques generally are useful only in processing flat substrates. If a substrate has a relief (i.e. has a non-planar topography) it is exceedingly difficult to fabricate structures on the substrate by flat conventional contact printing techniques. To this end, conventional photolithographic masks are substantially flat. As a result, it is exceedingly difficult to place the mask in contact with, or in close enough proximity to, all points on the surface of a substrate to enable accurate image projection onto the substrate. In regions of the substrate where the photolithographic mask is not in contact with, or in close enough proximity to, the substrate, diffractive effects result in poor resolution and ultimately a poor transfer of the pattern from the mask to the photoresist.

As the use of non-planar substrates gains acceptance, it is clear there is a need for the photolithographic imaging process which overcomes the drawbacks of conventional contact printing describe above.

### SUMMARY OF THE INVENTION

According to an illustrative embodiment of the present invention, an image lithography multi-level mask includes a substrate having a surface with at least one mesa and at least one valley. At least one substantially opaque element is disposed over the valley.

According to another illustrative embodiment of the present invention, an image lithography multi-level mask includes a substrate having a surface with at least one mesa. The mesa has a first transmittance and the substrate has a second transmittance. The first transmittance is greater than or equal to the second transmittance.

According to yet another illustrative embodiment of the present invention, an image lithography method includes providing a substrate and locating a multi-level mask over the substrate. The multi-level mask has at least one mesa which is complementary to a region of the substrate. The method further includes irradiating the multi-level mask with a radiation source to selectively expose a resist layer disposed over the substrate.

According to yet another illustrative embodiment a method of forming features on a substrate includes providing a substrate and locating a multi-level mask over the substrate, where the multi-level mask includes at least one valley and at least one substrate. The multi-level mask is irradiated to selectively expose a resist layer disposed over first and second levels of the substrate.

According to yet another illustrative embodiment of the present invention, a method of fabricating a multi-level mask includes providing a top flat mask and a bottom flat mask, and locating a top flat mask over a bottom flat mask. The top flat mask is selectively etched to form at least one mesa and at least one valley.

According to yet another illustrative embodiment of the present invention, a method of fabricating a multi-level mask includes providing a substrate; forming at least one mesa over the substrate; forming at least one valley on the substrate; and forming at least one opaque element on at least one of the mesas and forming at least one opaque element in at least one of the valleys.

According to yet another exemplary embodiment of the present invention, a method for providing backside alignment includes providing a substrate; disposing the substrate onto a valley of a multi-level mask, wherein the multi-level mask has a first mesa, and alignment patterns on the first mesa; and aligning a mask to the alignment patterns on the first mesa, wherein the substrate is disposed between the multi-level mask and the mask.

According to yet another exemplary embodiment of the present invention, an apparatus for providing backside mask alignment for a substrate includes a multi-level mask having a valley and a first mesa, and a first alignment pattern on the first mesa; and a mask having second alignment pattern opposed to the first mesa.

Among other advantages, the multi-level mask according to exemplary embodiments of the present invention enables accurate pattern transfer to a non-planar substrate in a single mask step. This facilitates the fabrication of features on multi-level of the substrate that are both accurately defined and accurately located relative to one another.

Defined Terms

As used herein, “non-planar” means having multiple levels or regions above and/or below a principle planar surface (baseline level) of a substrate.

As used herein, “opaque” means electromagnetic radiation of a particular wavelength or wavelength spectrum is substantially absorbed and/or substantially reflected, so that blocked radiation does not expose radiation sensitive layer(s) during lithography.

As used herein, “transparent” means electromagnetic radiation of a particular wavelength or wavelength spectrum is neither substantially absorbed nor substantially reflected, so that transmitted radiation can be used to expose a radiation sensitive layer(s) during lithography.

As used herein, “transmittance” refers to the product of the transmission coefficient and the thickness of a particular layer of material.

As used herein, the term “close proximity” means close enough to an object that diffractive effects are substantially negligible.

### BRIEF DESCRIPTION OF THE DRAWINGS

The invention is best understood from the following detailed description when read with the accompanying drawing figures. It is emphasized that the various features are not necessarily drawn to scale. In fact, the dimensions may be arbitrarily increased or decreased for clarity of discussion.

FIG. 1 is a cross-sectional view of a multi-level mask according to an exemplary embodiment of the present invention.

FIGS. 2(a)-2(b) are cross-sectional views of a multi-level mask according to an exemplary embodiment of the present invention.

FIG. 2(c) is a cross-sectional view of a non-planar substrate showing etched features formed using a multi-level mask on non-planar topography substrate according to an exemplary embodiment of the present invention.

FIG. 3 is a cross-sectional view of a non-planar substrate showing etched features formed using a multi-level mask according to an exemplary embodiment of the present invention.

FIG. 4 is a cross-sectional view of a non-planar substrate showing etched features formed using a multi-level mask according to an exemplary embodiment of the present invention.

FIGS. 5(a)-5(g) are cross-sectional views of an illustrative process sequence used to form the structure of FIG. 4 according to an exemplary embodiment of the present invention.

FIGS. 6(a)-6(c) are cross-sectional views showing an illustrative method for fabricating a multi-level mask in accordance with an exemplary embodiment of the present invention.

FIGS. 7(a)-7(c) are cross-sectional views showing an illustrative method for fabricating a multi-level mask in accordance with an exemplary embodiment of the present invention.

FIGS. 8(a)-8(c) are cross-sectional views showing an illustrative method for fabricating a multi-level mask in accordance with an exemplary embodiment of the present invention.

FIGS. 9(a)-9(e) are cross-sectional views showing an illustrative method for fabricating a multi-level mask in accordance with an exemplary embodiment of the present invention.

FIGS. 10(a)-10(c) are cross-sectional views showing an illustrative method for fabricating a multi-level mask in accordance with an exemplary embodiment of the present invention.

FIGS. 11(a)-11(c) are cross-sectional views showing an illustrative method for fabricating a multi-level mask in accordance with an exemplary embodiment of the present invention.

FIGS. 12(a)-12(c) are cross-sectional views showing an illustrative method for fabricating a multi-level mask in accordance with an exemplary embodiment of the present invention.

FIGS. 13(a)-13(c) are cross-sectional views of a multi-level mask used in back side processing, according to an exemplary embodiment of the present invention.

FIG. 14 is a cross-sectional view showing a multi-level mask passively aligned to a non-planar substrate in accordance with an exemplary embodiment of the present invention.

FIG. 15 is a cross-sectional view showing a multi-level mask passively aligned to a non-planar substrate in accordance with an exemplary embodiment of the present invention.

### DETAILED DESCRIPTION

In the following detailed description, for purposes of explanation and not limitation, exemplary embodiments disclosing specific details are set forth in order to provide a thorough understanding of the present invention. However, it will be apparent to one having ordinary skill in the art having had the benefit of the present disclosure, that the present invention may be practiced in other embodiments that depart from the specific details disclosed herein. Moreover, descriptions of well-known devices, methods and materials may be omitted so as to not obscure the description of the present invention.

For the purpose of clarity of discussion, the description of the illustrative embodiments described below will center primarily on ultraviolet (UV) photolithography, where UV light is used for photoresist patterning. Therefore, unless otherwise specified, the materials and structural dimensions are specific to UV photolithography. Of course, the present invention may be used in other lithographic techniques. These include, but are not limited to lithography, using other electromagnetic radiation. Illustratively, photolithography using other portions of the optical spectrum and x-ray lithography may be used. As can be appreciated, these other lithographic techniques may require the multi-level mask of the invention of the present disclosure to be fabricated from materials that are different than those disclosed herein. Moreover, structural dimensions may be different then those described herein. Materials used for these alternative lithographic techniques will be chosen to be substantially transparent or substantially opaque, as needed, to form a multi-level mask in accordance with the present invention. Moreover, in same instances, the materials used to form the multi-level mask of the present invention will require etch selectivity relative to one another. These materials and structural dimensions will be within the purview of one having ordinary skill in IC, OIC and micromachined features fabrication.

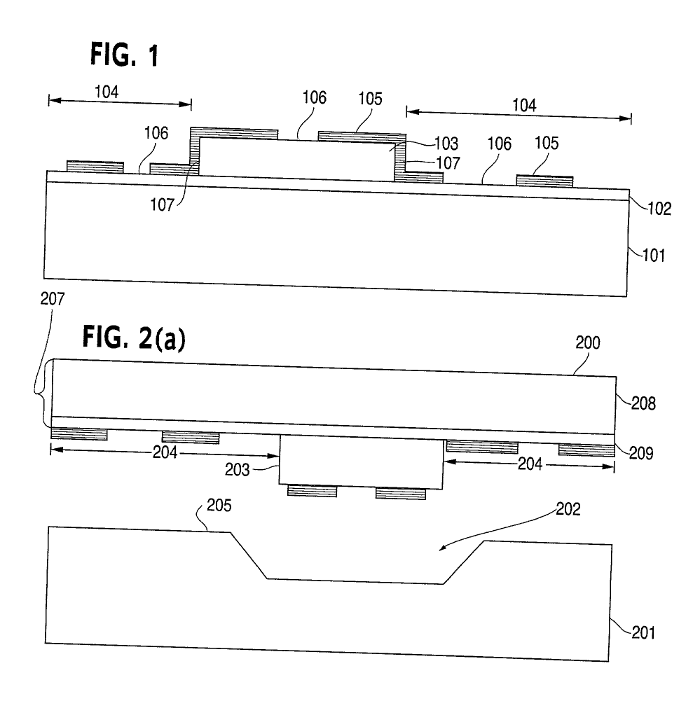

FIG. 1 shows a multi-level mask 100 according to an exemplary embodiment of the present invention. An etch-stop layer 102 is disposed over a base layer 101. A mesa 103 is disposed over the etch-stop layer 102. Valleys 104 are disposed adjacent mesa 103. Opaque elements 105 are disposed in the valleys 104 and on the mesa 103 as shown. Openings 106 in the opaque portions enable the selective transmission of light through the multi-level mask 100 to photo-sensitive/patternable material during photolithography. Usefully base layer 101 and mesa 103 are transparent. Illustratively, the base layer 101 has a first transmittance, and the mesa 103 has a second transmittance. The transmittance of the mesa 103 is greater than or equal to the transmittance of the base layer 101. It is of interest to note that the transmittance of the mesa does not include the transmittance of the base layer. That is, the transmittance of the mesa refers only to the product of the transmission coefficient of the mesa and the thickness of the mesa layer. The multi-level mask 100 of the illustrative embodiment of FIG. 1 enables pattern transfer in a single mask step to substrates having a substantially non-planar topography. This facilitates the fabrication of features on the substrate that are both accurately defined and accurately spaced relative to one another.

It is of interest to note that opaque elements 105 illustratively extend over sidewalls 107 of mesa 103, as may be useful in reducing unwanted scattering of radiation. Finally, while sidewalls 107 of multi-level mesa 103 are substantially perpendicular to base layer 101, this is not essential. To this end, the mesa can having sloping sidewalls (not shown). In fact, opaque elements 105 can be disposed on the sloping sidewalls. This will allow the mask to pattern corresponding sloping sidewalls of a substrate. For example, if the mesa has sloping sidewalls, then the multi-level mask can be used to pattern features on angled sidewalls of anisotropically etched <100> silicon (which has sidewalls angled at 54.7° with respect to the substrate surface).

Exemplary Embodiments of a Multi-level Mask and Methods of Use

Presently, exemplary embodiments of a multi-level mask according to the present invention are described. In addition, exemplary embodiments of the use of a multi-level mask are described. These embodiments are merely illustrative and are not intended to limit the present invention.

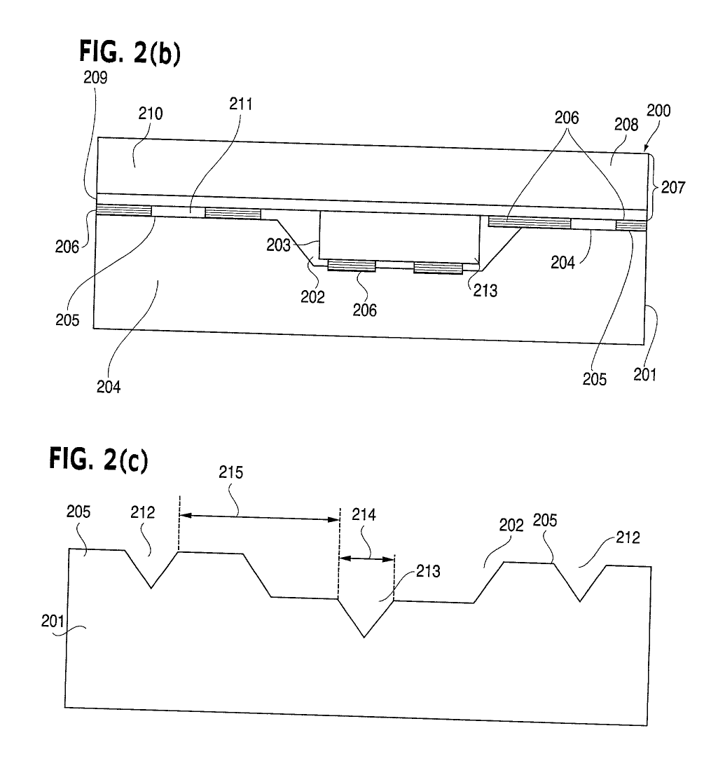

Turning to FIG. 2(a), a multi-level mask 200 is disposed above a substrate 201, which is non-planar. The substrate 201 has a recess 202 which is substantially complementary to a mesa 203 of multi-level mask 200. Valleys 204 in the multi-level mask 200 are substantially complementary to a baseline level 205 of the substrate 201. The multi-level mask 200 includes opaque elements 206 disposed on the mesa 203 and on the valleys 204. Illustratively, the multi-level mask 200 includes a base layer 207 comprising a layer 208 and an etch-stop layer 209, which is useful during fabrication of multi-level mask 200. Usefully, base layer 207 and mesa 203 are transparent. Illustratively, mesa 203 has a transmittance which is greater than or equal to the transmittance of base layer 207.

For purposes of illustration and not limitation, multi-level mask 200 may be used in ultra-violet (UV) photolithographic processing. In this example, the base layer 207 and mesa 203 can be silica. The etch-stop layer may be Si₃N₄, Al₂O₃ or Ta₂O₅; and the opaque elements 206 are metal, such as chromium.

FIG. 2(b) shows the multi-level mask 200 disposed over the substrate 201. As can be seen, the mesa 203 is substantially disposed in recess 202. Moreover, the valleys 204 adjacent mesa 203 are disposed over the baseline level 205 of substrate 201. During a photolithographic step, light is incident upon the backside portion 210 of the multi-level mask 200 as shown. Light is transmitted though the openings 211 between opaque elements 206 to a photoresist layer (not shown) disposed over the substrate 201. The photoresist layer (not shown) is selectively exposed, and pattern transfer of the pattern of multi-level mask 200 is achieved.

It is important to note that the resist layer is usefully conformal to the non-planar topography of the substrate to be patterned by the multi-level mask of the present invention. The resist layer (in the illustrative embodiment a photoresist) is a layer of material which is sensitive to the radiation used in the particular type of lithography chosen. It is conformally coated on the surface of the substrate to be patterned (in this instance substrate 201) by being sprayed-on or applied as a laminate.

By virtue of the multi-level nature of multi-level mask 200, pattern transfer may be achieved in substrates (such as substrate 201), which have a substantially non-planar topography. To this end, the problems described previously associated with diffractive effects using conventional flat multi-level masks to achieve pattern transfer in recesses, such as recess 202, is substantially overcome by virtue of the present invention. To wit, because the mesa 203 extends into recess 202, the opaque elements 206 on mesa 203 are maintained in contact with or in close proximity to the bottom surface of recess 202. Usefully, mesa 203 has a height that is approximately equal to the depth of recess 202. Illustratively, the height of mesa 203 is within approximately ±10 μm to approximately ±1 μm the depth of recess 202. Moreover, the distance (gap spacing) between the opaque elements 206 disposed over valleys 204 and the baseline level 205 of substrate 201 is approximately the same as the distance (gap spacing) between the opaque elements 206 of mesa 203 and the bottom surface of recess 202.

Finally, it is of interest to note that multi-level mask 200 may be used as both a contact multi-level mask or as a proximity multi-level mask. If used as a proximity multi-level mask, multi-level mask 200 would be held above and in close proximity to the surfaces of the substrate 201. Illustratively, the proximity of multi-level mask 200 to substrate 201 is in the range of less than approximately 4.0 μm.

FIG. 2(c) shows the resultant structure after pattern transfer by multi-level mask 200 and etching by standard technique (e.g. anisotropic wet etch of <100>silicon substrate). Grooves 212 are formed at baseline level 205, while groove 213 is formed in recess 202. Because the mesa 203 is substantially complementary to recess 202, it may be in contact with or in close proximity to the lower surface of the recess 202. As such, diffractive effects are minimized if not eliminated, and the width 214 of groove 213 is accurately defined. Moreover, because a single multi-level mask step may be used to achieve pattern transfer, the distance 215 between grooves 213 and 212 may be accurate to better than approximately −1 μm to approximately +1μm. This is a significant improvement over conventional processing using multiple masks or by diffractive proximity masks. Finally, it is of interest to note that the multi-level mask according to an illustrative embodiment of the present may be used in the fabrication of a variety of features. For example, features such as metal traces, contact pads, solder pads and patterned thin films may be fabricated on baseline level 205 and in recess 202.

As can be readily appreciated, the multi-level mask 200 of the illustrative embodiment of FIGS. 2(a) and 2(b) may be a portion of a larger multi-level mask having a plurality of mesas 203 and valleys 204. The different levels (e.g. baseline levels and recesses) of a substrate such as substrate 201 may be patterned using the same multi-level mask in the same step. This facilitates accurately defined features and accurate location of and spacing between features. Moreover, these features can be at different levels of the substrate. As such, a variety of topographies may be selectively formed by using multi-level masks according to exemplary embodiments of the present invention. Some features formed on substrates having a non-planar topography have been described. Others illustrating the present invention will be further described presently. Still others within the purview of the artisan of ordinary skill may be fabricated through use of the present invention.

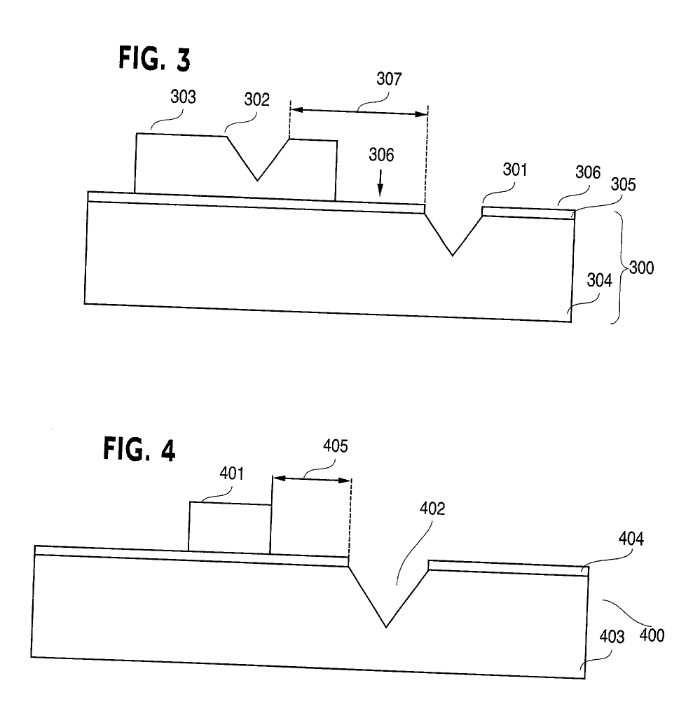

FIG. 3 shows a substrate 300 having various features at two levels. A groove 301 is formed in the substrate 300. A groove 302 is formed in a device layer 303 disposed over the substrate. According to the illustrative embodiment of FIG. 3, the substrate 300 may be a silicon-on-insulator (SOI) having a handle layer 304 and a layer of insulator 305 such as silicon dioxide.

As can be appreciated, groove 301 can be formed using patterns disposed on a mask mesa, and groove 302 can be formed using patterns disposed on a mask valley. Because the mesa is substantially complementary to baseline level 306 and the valley is substantially complementary to the pedestal 302, the multi-level mask may be located substantially in contact with or in close proximity to all portions of the surface of substrate 300. Moreover, because the exposure of all levels of a substrate may be carried out in a single mask step by virtue of the multi-level mask according to an illustrative embodiment of the present invention, the distance 307 between the grooves 301 and 302 may be very accurate; illustratively within approximately ±1 μm.

As referenced above, the multi-level mask may be used to fabricate a variety of structures from substrates having a substantially non-planar topography. Specifically, the single multi-level mask according to the exemplary embodiment of the present invention may be used to pattern many types of features on multiple levels of a substrate. For example, a metal pattern (not shown) may be formed at a baseline level and v-grooves may be formed in the bottom surface of a recess.

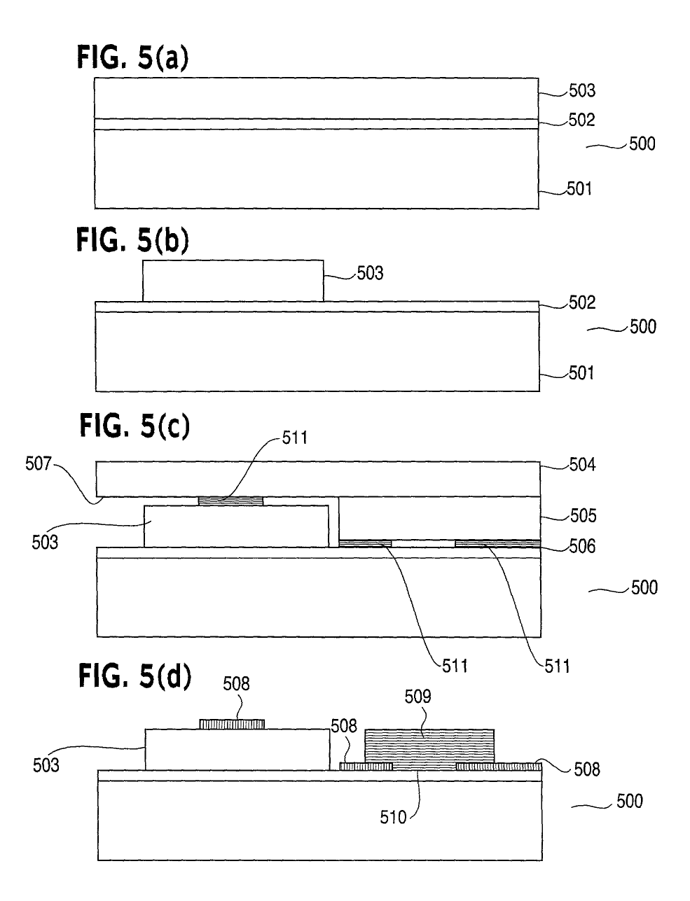

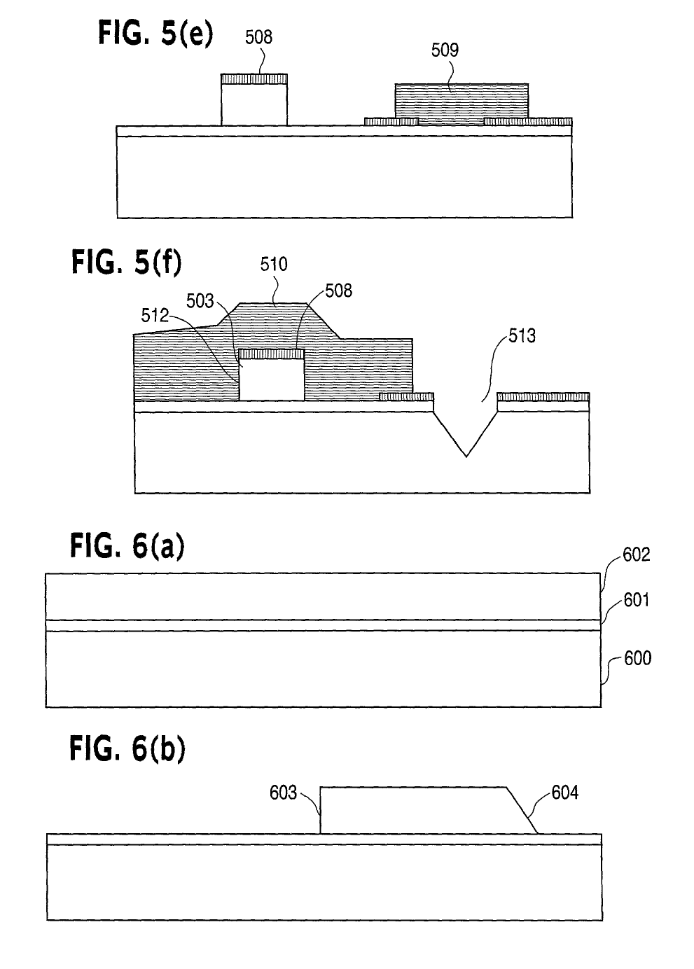

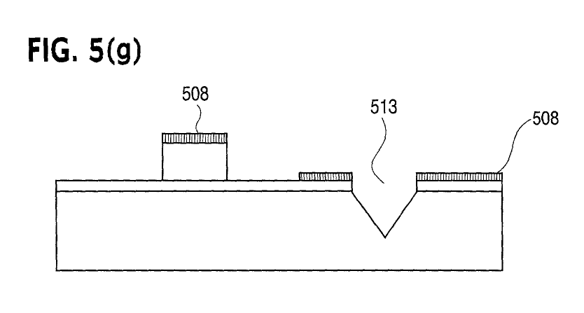

FIG. 4 shows another illustrative structure having features formed using a multilevel mask according to an exemplary embodiment of the present invention. According to the illustrative structure shown in FIG. 4, a substrate 400 has features including a pedestal 401 and a groove 402. The pedestal 401 may be formed from a device-layer of an integrated optical circuit. The substrate 400 may have a handle-layer 403 and an insulator layer 404. Through the use of a multi-level mask according to an exemplary embodiment of the present invention, the pedestal 401 and the v-groove 402 may be defined in the same photolithographic step. This enables very accurate location of groove 402 and pedestal 401. Moreover, this enables spacing 405 between pedestal 401 and v-groove 402 to be very accurate as well. FIGS. 5(a)-5(f) show an illustrative technique for fabricating the structure shown in FIG. 4.

FIG. 5(a) shows a substrate 500, which illustratively includes a handle-layer 501 and an insulator layer 502. Layer 503 may be disposed over the insulator layer 502. As shown in FIG. 5(b), a portion of layer 503 has been removed by standard technique. Removal of the portion of layer 503 may be done relatively inaccurately (e.g. where the edges have an accuracy of ±20 μm).

FIG. 5(c) shows a multi-level mask 504 according to an illustrative embodiment of the present invention disposed over the substrate 500 and layer 503. The multi-level mask includes opaque elements 511 in valley 507 and over mesa 505. The multi-level mask 504 is substantially identical to the multi-level masks described in the illustrative embodiments described above. It is of interest to note, however, that whereas in the illustrative embodiments described above the mesa of the multi-level mask is disposed in a recess in the substrate, in the illustrative embodiment presently described, mesa 505 is in contact with or in close proximity to baseline level 506 of the substrate 500. Moreover, while in the previously described illustrative embodiments, the valley of multi-level mask is disposed primarily at the baseline level 506, in the illustrative embodiment presently described, valley 507 of multi-level mask 504 is disposed over layer 503 which is raised above the baseline level 506 of substrate 500. As can be readily appreciated, a salient feature of the multi-level mask of the present invention is its ability to be disposed substantially in contact with or in close proximity to a variety of topographies of non-planar substrates. This enables accurate pattern transfer in a single photolithographic step.

As shown in FIG. 5(d), after illumination by a radiation source, the photoresist 508 that was protected by opaque elements 511 remains on the top-surface of layer 503 and on the baseline level 506 of substrate 500. In preparation for a dry-etching process step, such as reactive ion etching (RIE) protective layer 509 may be disposed over opening 510. This protective layer 509 is optional depending on the reactive ion etching process to be used, and the thickness of layer 503.

As shown in FIG. 5(e), a dry-etch step is carried out which results in the removal of the portion of layer 503 that is not protected by exposed photoresist 508.

Turning to FIG. 5(f), a protective layer 510 is disposed over layer 503 and exposed photoresist 508. This protective layer 510 is used to protect the sidewalls 512 during a wet-etch sequence which forms groove 513.

As shown in FIG. 5(g), the protective layer 510 has been removed, and layer 503 and pit 512 have been formed. The exposed photoresist 508 may then be removed and the structure shown in FIG. 4 is realized. Advantageously, because the pattern transfer needed to form pedestal 401 and groove 402 may be carried out in a single mask step using the multi-level mask of the present invention, both the location of and spacing between pedestal 401 and groove 402 may be accurately defined; again, to within approximately −1.0 μm to approximately +1.0 μm.

Multi-Level Mask Fabrication

Multi-level masks for contact or proximity lithography according to exemplary embodiments of the present invention may be fabricated by techniques which are described presently. The presently described techniques are illustrative and are not intended to limit the invention.

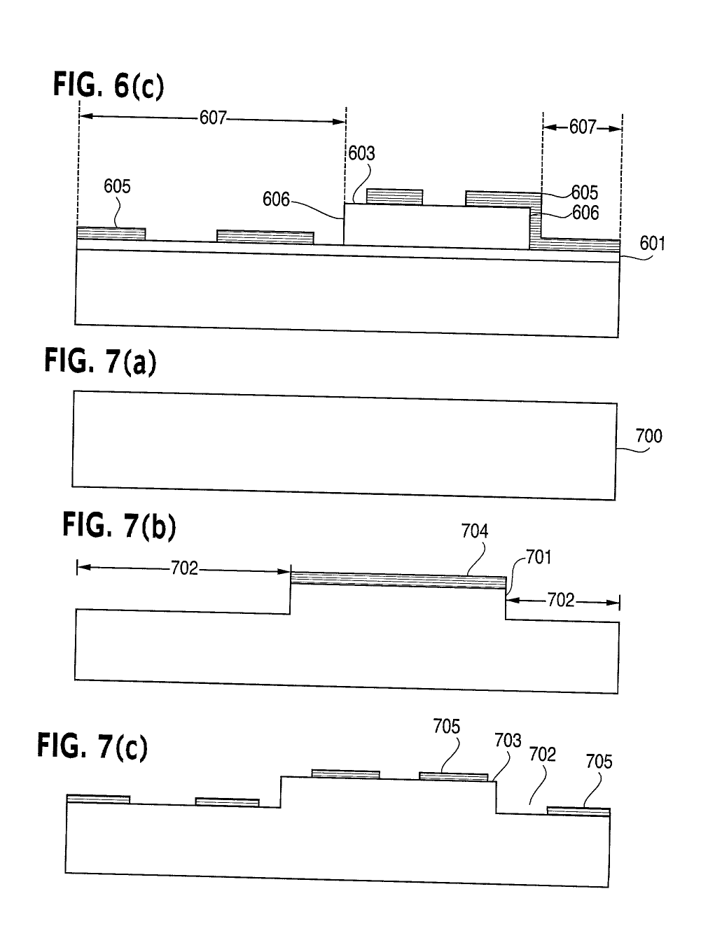

Turning to FIG. 6(a), a base layer 600 may be used in forming the multi-layer multi-level mask. Illustratively, base layer 600 is silica. An etch-stop layer 601 is formed on the base layer 600. A top layer 602 is formed over the etch-stop layer 601.

According to the illustrative embodiment shown in FIG. 6(a), the etch-stop layer 601 usefully is made of a material that is transparent at wavelengths typically used in UV photolithography. Illustratively, these wavelengths are in the range of approximately 250 nm to approximately 500 nm. (As described above, the multi-level mask of the present invention may be used in lithographic processes. In this case, other materials may be used). Moreover, the etch-stop layer 601 usefully is made of a material that is readily bonded to silica or other ultraviolet radiation transparent materials used for top layer 602 and base layer 600. Illustratively, the base layer 600 and top layer 602 are silica. Finally, the etch-stop layer 601 usefully is made of a material that resists wet or dry etchants that will etch top layer 602 and base layer 600. For example, if the top layer 602 and the base layer 600 are silica, the etch-stop layer 601 may be alumina (Al₂O₃), which is resistant to etchants, such as hydrofluoric acid which etches silica. Other illustrative materials which may be used for etch-stop layer 601 include silicon nitride, tantalum pentoxide, and polycarbonates.

The materials referenced above are merely illustrative. Accordingly, other materials may be used for the etch-stop layer 601, top layer 602 and base layer 600. Examples of UV-transparent materials that may be combined in a variety of ways to realize the structure shown in FIG. 6(b) include: LiF, MgF₂, CaF₂, SrF₂, KCl and other glasses and crystalline materials, and metal oxides well known to one having ordinary skill in the art. Moreover, other metal oxides such as magnesium oxide may be used.

As shown in FIG. 6(b), a portion of the top layer 602 has been removed by standard multi-level masking and etching technique. The removal of a portion of the top layer 602 results in the formation of the mesa 603 and valleys 607 adjacent thereto. The etching of a portion of the top layer 602 may be done relatively inaccurately (e.g. the edges may be located with a tolerance of approximately±10 μm to approximately 20 μm ), and in fact may be done with a wet isotropic etching if the top layer is relatively thin (e.g. less than approximately 200 μm). As shown in FIG. 6(b), the mesa 603 may have sloping sidewalls such as sidewall 604.

As shown in FIG. 6(c), opaque elements 605 may be formed on the mesa 603 as well as in valleys 607. Moreover, opaque elements 605 may be formed on both sidewalls 606 of mesa 603 or on one of the sidewalls 606, as shown. Usefully, the mesa 603 and etch-stop layer 601 are patterned with opaque materials in the same step to provide accurate alignment between the opaque elements 605 on the mesa 603 and the opaque elements 605 on the etch-stop layer 601. The patterning of the opaque material may be effected by standard e-beam lithography or similar techniques.

Illustratively, opaque material such as a suitable metal is deposited or sputtered on the mesas and valleys, as desired. The opaque material may be deposited on the horizontal surfaces of the mesas and valleys, or it can be deposited conformally thereto. An e-beam resist is then conformally applied. This e-beam resist is patterned with an e-beam. This patterning may be done on different level by refocusing the e-beam, or by vertically moving the mask. Finally, the opaque material is etched by standard technique. Another illustrative technique may be used to form opaque elements on the multi-level mask of the present invention. This illustrative technique is similar to the one described immediately above, except that the e-beam resist is deposited and patterned in a first step. Thereafter, the opaque material is deposited and patterned by a standard lift-off technique. Additionally, a standard direct-write technique may be used to pattern the opaque material. In this instance, the opaque material is directly written from the vapor phase, with opaque material being deposited wherever the electron beam strikes. Finally, the material used for opaque elements 605 is illustratively metal, such as chromium or other suitable material. Of course, other material may be used for opaque elements 605.

Turning to FIG. 7(a)-7(c), another illustrative method for making a multi-level mask according to an exemplary embodiment of the present invention. FIG. 7(a) shows a base layer 700 which is illustratively silica. The base layer 700 may be patterned by well known techniques to define the mesas and valleys thereon. As shown in FIG. 7(b), mask layer 704 protects a portion of base layer 700 during a standard etching technique, which forms a mesa 701 and valleys 702. Illustratively, a dry-etching technique may be used to achieve a well-defined valley depth/mesa height. Alternatively, a wet-etch step may be used.

Finally, as shown in FIG. 7(c), the multi-level mask 704 is removed, and opaque elements 705 are disposed both in the valleys 702 and on the mesa 703. The opaque elements 705 are illustratively metal, and are fabricated by standard e-beam lithography, such as those described above. Advantageously, the patterning of opaque material used to form opaque elements 705 is carried out in a single step. This provides accurate alignment between the opaque elements 705 disposed in the valleys 702 and the opaque elements 705 disposed on the mesa 703.

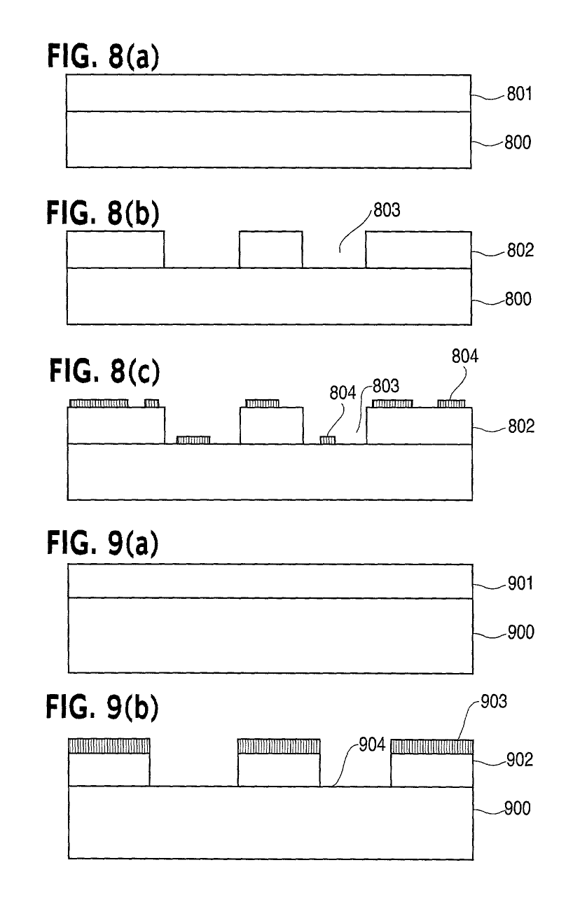

FIGS. 8(a)-8(c) show another illustrative method of fabricating a multi-level mask according to the present invention. FIG. 8(a) shows a base layer 800 which has a layer 801 disposed thereon. In this illustrative embodiment, base layer 800 and layer 801 are different materials. Illustratively, base layer 800 is alumina and layer 801 is silica. Of course, other materials may be used. Usefully, the materials for a multi-layer multi-level mask according to the present exemplary embodiment are selectably etchable. Moreover, the materials are usefully bondable to, or depositable upon one another by standard techniques. Illustratively, substrate 800 may be bonded to layer 801 by thermo-compression bonding or bonding with borosilicate glass. Alternatively, layer 801 may be deposited on substrate 800 by chemical vapor deposition (CVD).

FIG. 8(b) shows the formation of mesas 802 and valleys 803 by selective etching of the top layer 801. The etching technique is illustratively a standard wet etching technique and provides mesas 802 having accurate heights, and valleys 803 with accurate depths.

FIG. 8(c) shows the patterned opaque portions 804 of the multi-level mask. The patterned portions are disposed on mesas 802 and in valleys 803. The opaque portions 804 are illustratively metal (e.g. chromium) which are deposited, and patterned by standard techniques, such those described above.

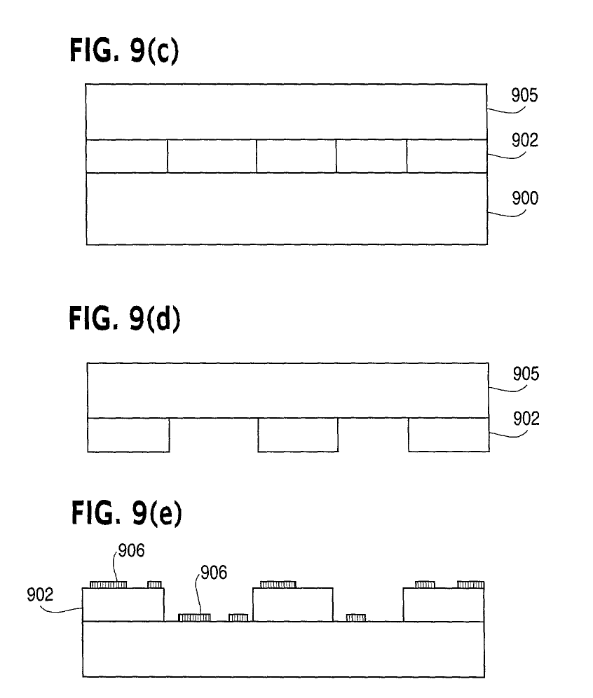

FIG. 9(a)-9(e) show another illustrative technique for fabricating a multi-level mask according to the present invention. In the present embodiment, the multi-level mask may be made from a single material. Illustratively, the material is silica or alumina, although other materials may be used in keeping with the present invention.

As shown in FIG. 9(a), a layer 901 is disposed over a bottom layer 900. Layer 901 may be silica, and bottom layer 900 may be silicon. Layer 901 may be deposited on or bonded to the bottom layer 900. The deposition may be by CVD or by thermal oxidation. The bonding may be achieved by direct bonding or with a thin film of glass (not shown) such as borosilicate glass between layer 901 and bottom layer 900. In addition, layer 901 may be bonded to bottom layer 900 with a removable bonding material. These material include polymers, phenol, BCB and UV opaque materials. Layer 901 may also be thermo-compression bonded to bottom layer 900. Finally, as described in more detail herein, bottom layer 900 may be a sacrificial-layer or handle-layer.

As shown in FIG. 9(b), layer 901 is masked and etched selectively with an etchant which does not etch bottom layer 900. This results in the formation of mesas 902 and valleys 904. Illustrative etching techniques may be wet or dry selective etching techniques. Thereafter, etchant mask 903 is removed.

As shown in FIG. 9(c), a base layer 905 is bonded to the mesas 902. Again, a thin layer of glass such as borosilicate glass may be provided between base layer 905 and mesas 902 to facilitate bonding. Base layer 905 is illustratively of the same material as the material used for pedestals 902.

As shown in FIG. 9(d), the bottom layer 900 is removed. The removal of the bottom layer 900 is by a standard etching technique with an etchant which will not attack the material used for the pedestals 902 or base layer 905. For example, in the illustrative embodiment in which the base layer 905 and pedestals 902 are silica and bottom layer 900 is silicon, EDP or KOH may be used as the etchant. Alternatively, if the bottom layer 900 is bonded to pedestals 902 with an adhesive, it may be removed through use of solvent or by baking. Finally, as is shown in FIG. 9(e), opaque elements 906 are formed on pedestals 902 and in valleys 905. The opaque elements 906 may be formed by standard deposition and patterning techniques such as by electron beam patterning, as described more fully above.

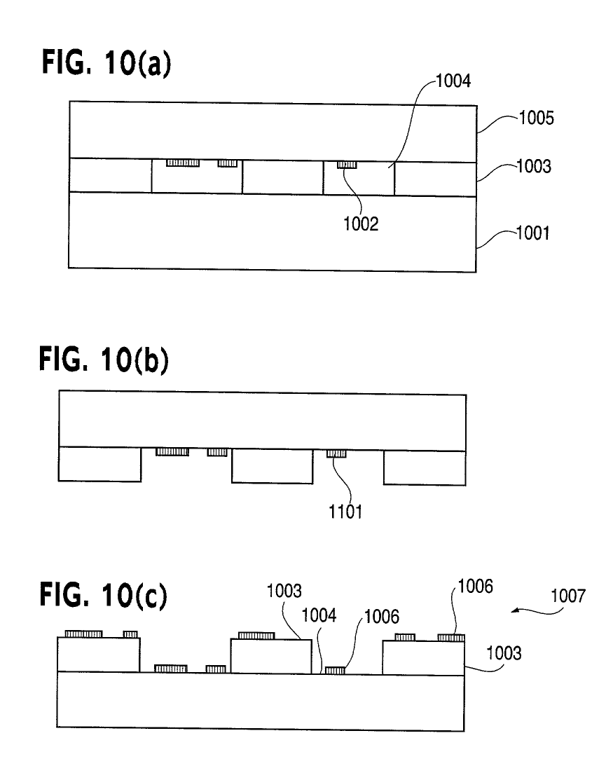

FIGS. 10(a)-10(c) show another illustrative technique for fabricating a multi-level mask. The technique according to the present illustrative embodiment is similar to the illustrative technique described in connection with FIGS. 9(a)-9(e). In the present illustrative technique, opaque elements 1002 are formed on base layer 1005 before it is bonded to mesas 1003 disposed on bottom layer 1001. Opaque elements 1002 may be formed of any opaque material which is effective in blocking the radiation source used for the desired photolithographic process, and base layer 1005 and mesas 1002 may be silica or alumina. Bottom layer 1001, which is illustratively silicon, is removed as shown in FIG. 10(b).

As shown in FIG. 10(c), opaque portions 1002 are formed on mesas 1003 by standard technique. Thereby, multi-level mask 1007 has opaque elements 1002 in valleys 1004 and on mesas 1003.

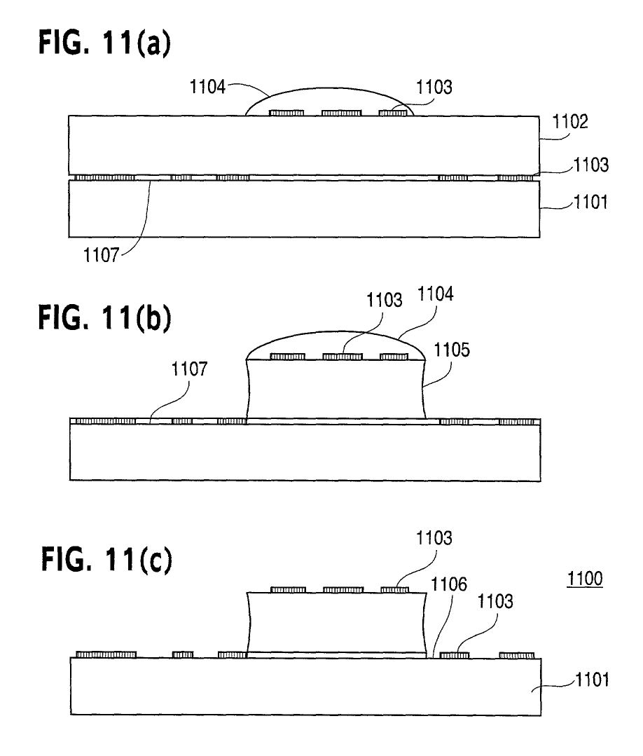

FIGS. 11(a)-11(d) show another illustrative technique for fabricating a multilevel mask according to the present invention. FIG. 11(a) shows a lower flat mask 1101 bonded to an upper flat mask 1102. The multi-level masks may be bonded together with a relatively thin film of adhesive 1107. Illustratively, the adhesive 1107 has a thickness in the range of approximately 5 μm to approximately 25 μm. The adhesive 1107 is illustratively UV transparent. For example, fluoropolymers may be used as the adhesive. Moreover, the adhesive 1107 is of a material that is not readily etched by etchants which will etch the upper and lower flat masks 1102 and 1101, respectively. A portion of the top mask 1102 is masked with a temporary mask 1104.

As shown in FIG. 11(b), the unprotected portion of the top mask 1102 is etched by standard technique. A pedestal 1105 is formed having opaque elements 1103 disposed thereon. The temporary mask 1104 is then removed. Moreover, the adhesive 1107 used to bond the top flat mask 1102 to the bottom flat mask 1101 may be removed from the surface of the bottom flat mask 1101. As shown in FIG. 11(c), a multi-level mask 1100 is formed having opaque elements 1103 disposed on the top surface of pedestal 1105 as well as in valleys 1106.

Alternative Embodiments

The illustrative embodiments described thus far have primarily focused upon a two-level multi-level mask for use in lithographic processes. Described presently are other illustrative embodiments of the present invention. These presently described embodiments are illustrative of the present invention and are in no way limiting thereof.

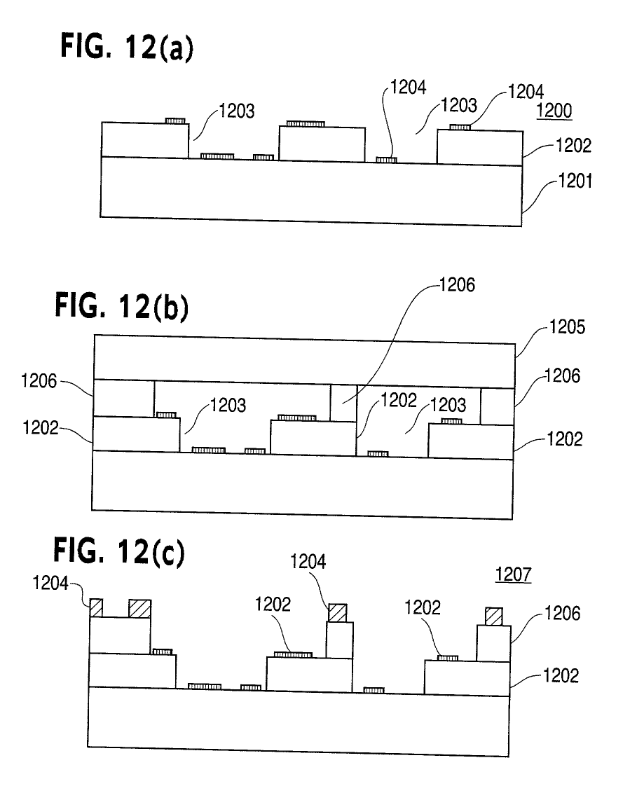

FIGS. 12(a)-12(c) show the fabrication of a three-layer multi-level mask. FIG. 12(a) shows a two-level mask having a base layer 1201 with pedestals 1202 and valleys 1203. Opaque portions 1204 are formed on the pedestals and in the valleys. The two-level multi-level mask 1200 may be fabricated by the illustrative techniques described above. Moreover, the two-level mask 1200 may be fabricated from materials described previously.

FIG. 12(b) shows the two-level mask 1200 bonded with a sacrificial layer 1205 which includes mesas 1206. The sacrificial layer 1205 is illustratively silicon, although other materials may be used in its place. FIG. 12(c) shows sacrificial layer 1205 removed by etching or other technique, leaving a three-layer multi-level mask 1207. Opaque elements 1204 are selectively disposed on mesas 1206 and 1202. These opaque elements may be formed by standard techniques, such as e-beam patterning described more fully above.

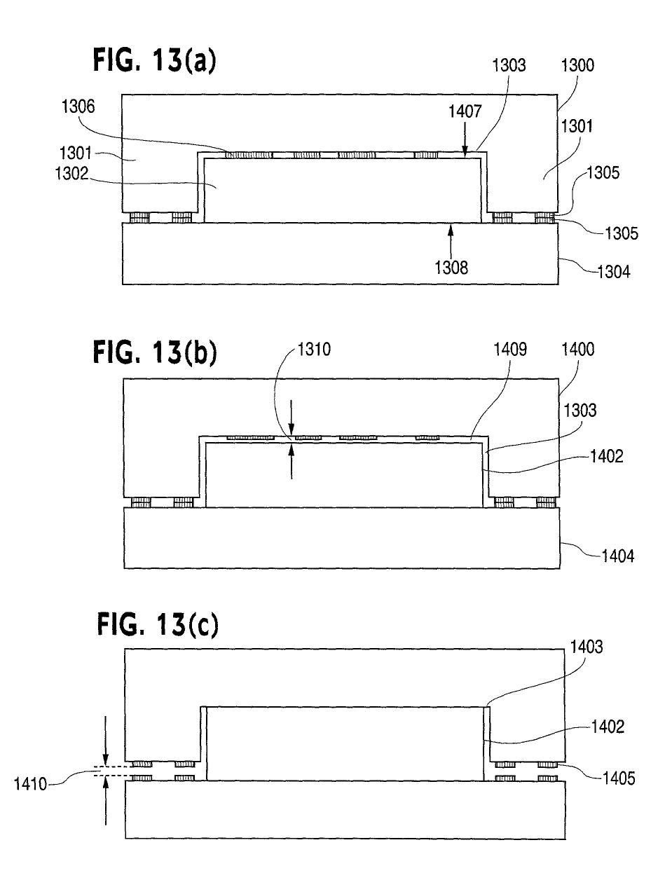

FIGS. 13(a)-13(d) show an illustrative embodiment of the present invention, which is particularly useful in providing backside alignment for multi-level masks. FIG. 13(a) shows a multi-level mask 1300 having mesas 1301 which illustratively extend beyond the edges of a wafer 1302 to be patterned. The multi-level mask has a valley 1303 which receives the wafer 1302. The pedestals 1301 of the multi-level mask ultimately contact a flat multi-level mask 1304. This alignment between pedestals 1301 and flat multi-level mask 1304 may be achieved using raised portions 1305. Opaque elements 1306 are disposed in valley 1303. The multi-level mask 1300 and flat multi-level mask 1304 are illustratively contacted and aligned so that their opaque patterns are aligned. Wafer 1302 may be exposed from a first side 1307 and a second side 1308.

FIG. 13(b) shows an illustrative embodiment of the present invention including a gap 1309 between the multi-level mask 1300 and the flat multi-level mask 1304. As illustrated in the embodiment shown in FIG. 13(c), the gap spacing 1309 is between the wafer 1302 and the multi-level mask 1309. Usefully, the depth of the valley 1303 is selected so that the gap spacing 1309 is relatively small, on the order of approximately 5 μm or less.

Turning to 13(c), another illustrative embodiment of the present invention. In the illustrative embodiment shown in FIG. 13(c), the depth of valley 1303 is less than the thickness of wafer 1302. As such, a gap spacing 1310 is between the raised portions 1305 providing mask alignment. Again, the gap spacing 1310 is usefully as small as possible, on the order of 5 μm or less.

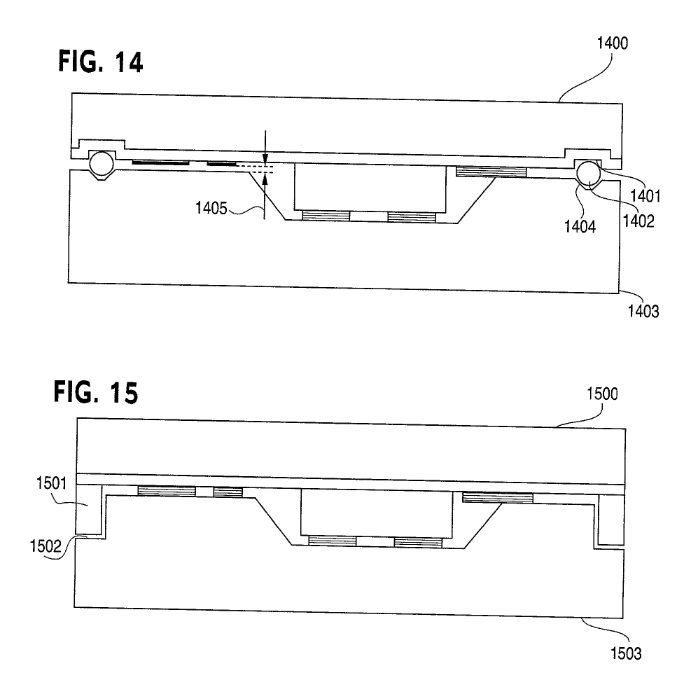

FIG. 14 shows an illustrative embodiment of the present invention incorporating alignment fiducials for aligning the multi-level mask to a substrate having a substantially non-planar topography. The multi-level mask 1400 is illustratively a two-level multi-level mask of the type previously described. Additionally, the multi-level mask 1400 includes pits 1401 for receiving alignment members 1402. Illustratively, alignment members 1402 are microspheres. The substrate 1403 to be patterned includes pits 1404 for receiving the alignment members 1402 as well. The pits 1401 and 1404 may be formed in the multi-level mask 1400 and substrate 1403, respectively, by standard techniques. For example, pits 1401 in multi-level mask 1400 may be formed by reactive ion etching; while pits 1404 in substrate 1403 may be formed by wet-anisotropic etching or reactive-ion etching. Advantageously, alignment members 1402 disposed in pits 1404 and 1401 provide for a well-defined spacing 1405 between multi-level mask 1400 and substrate 1403.

Alternatively, other types of alignment fiducials may be used to accurately align a multi-level mask to a substrate. FIG. 15 shows the use of alignment pedestals 1501 disposed on multi-level mask 1500. Complementary recesses 1502 in substrate 1503 receive pedestals 1501. The pedestals 1501 and recesses 1502 may be formed by standard fabrication techniques well known to one having ordinary skill in the art.

According to the illustrative embodiments shown in FIGS. 14 and 15, the multi-level masks may be used as contact multi-level masks or as proximity multi-level masks. When used as proximity multi-level masks, the multi-level mask does not actually touch the substrate. A space may be maintained between the multi-level mask and the substrate of less than approximately 4 μm in proximity lithography applications. Illustratively, the multi-level masks are passively aligned with a spacing between the multi-level mask and the substrate that may be determined by the size of the alignment fiducial (i.e. pits, positioning members and pedestals) used to provide the mechanical alignment.

The invention having been described in detail in connection through a discussion of exemplary embodiments, it is clear that various modifications of the invention will be apparent to one having ordinary skill in the art having had the benefit of the present disclosure. For example, the multi-level mask according to the illustrative embodiments disclosed may have two or three levels. Of course, more levels may be included in multi-level masks according to the present invention. Such modifications and variations are included within the scope of the appended claims.

In the claims: We claim:

1. A multi-level image lithography mask, comprising:
a base layer;
at least mesa disposed over said base layer, said at least one mesa having at least one valley adjacent thereto; and
at least one substantially opaque element disposed in said at least one valley, wherein said base layer and said at least one mesa are transparent.

2. A multi-level mask as recited in claim 1, wherein said base layer and said at least one mesa are of a same material.

3. A multi-level mask as recited in claim 1, wherein said base layer and said at least one mesa are of different materials.

4. A multi-level mask as recited in claim 1, wherein said at least one mesa has a transmittance that is greater than or equal to a transmittance of said substrate.

5. A multi-level mask as recited in claim 1, wherein said an etch-stop layer is disposed between said mesa and said base layer.

6. A multi-level mask as recited in claim 1, wherein the image lithography is chosen from the group consisting essentially of photolithography and x-ray lithography.

7. A multi-level mask as recited in claim 1, wherein said at least one valley is at a first level, said at least one mesa is at a second level, and at least one other mesa is at a third level.

8. A multi-level mask as recited in claim 7, wherein said at least one mesa and said at least one other mesa each have at least one opaque element disposed thereover.

9. A multi-level mask as recited in claim 2, wherein said material is silica.

10. A multi-level mask as recited in claim 2, wherein said material is alumina.

11. A multi-level mask as recited in claim 3, wherein said base layer is alumina and said at least one mesa is silica.

12. A multi-level mask as recited in claim 3, wherein said base layer is silica and said at least one mesa is alumina.

13. A multi-level image lithography mask, comprising:
a base layer; and
at least one mesa over said base layer, wherein said at least one mesa has a transmittance which is greater than or equal to a transmittance of said base layer.

14. A multi-level mask as recited in claim 13, wherein said at least one valley is disposed adjacent said at least one mesa.

15. A multi-level mask as recited in claim 14, wherein at least one opaque element is disposed in said valley.

16. A multi-level mask as recited in claim 13, wherein said base layer and said at least one mesa are of a same material.

17. A multi-level mask as recited in claim 13, wherein said base layer and said mesa are of different materials.

18. A multi-level mask as recited in claim 13, wherein said base layer and said mesa are transparent.

19. A multi-level mask as recited in claim 13, wherein the image lithography is chosen from the group consisting essentially of photolithography and x-ray lithography.

20. A multi-level mask as recited in claim 15, wherein said valley is at a first level, said at least one mesa is at a second level and at least one other mesa is at a third level.

21. A multi-level mask as recited in claim 20, wherein said at least one mesa and said at least one other mesa each have at least one opaque element disposed thereover.

22. A multi-level mask as recited in claim 16, wherein said material is silica.

23. A multi-level mask as recited in claim 16, wherein said material is alumina.

24. A multi-level mask as recited in claim 17, wherein said base layer is alumina and said at least one mesa is silica.

25. A multi-level mask as recited in claim 17, wherein said base layer is silica and said at least one mesa is alumina.

26. An image lithography method, comprising:
(a.) providing a substrate;
(b.) locating a multi-level mask over said substrate, said multi-level mask including at least one mesa which is substantially complementary to a region of said substrate; and
(c.) irradiating said substrate through said multi-level mask to selectively expose a resist layer disposed over said substrate.

27. A method as recited in claim 26, wherein (c.) is performed with electromagnetic radiation.

28. A method as recited in claim 27, wherein said electromagnetic radiation has a wavelength in the range of approximately 200 nm to approximately 500 nm.

29. A method as recited in claim 26, wherein said region is a recess in said substrate.

30. A method as recited in claim 26, wherein said region is a baseline level of said substrate.

31. A method as recited in claim 26, wherein said multi-level mask further includes at least one valley which is substantially complementary to another region of said substrate.

32. A method as recited in claim 31, wherein said at least one valley is at a first level and said at least one mesa is at a second level.

33. A method as recited in claim 31, wherein said another region is a pedestal over said substrate.

34. A method as recited in claim 31, wherein said another region is a baseline level of said substrate.

35. A method as recited in claim 31, wherein a spacing between opaque elements disposed over said at least one mesa and said region is substantially equal to a spacing between opaque elements disposed over said at least one valley and said another region.

36. A method as recited in claim 26, wherein said resist layer is exposed at more than one level of said substrate in a single step.

37. A method as recited in claim 26, wherein said region is a recess in said substrate and said another region is baseline level of said substrate.

38. A method as recited in claim 26, wherein said region is a baseline level of said substrate and said another region is a pedestal over said substrate.

39. A method of forming features on a substrate, the method comprising:
providing a substrate;
locating a multi-level mask over said substrate, said multi-level mask including at least one valley and at least one mesa; and
irradiating said substrate through said multi-level mask to selectively expose a resist layer disposed over first and second levels of said substrate in a single step.

40. A method as recited in claim 37, wherein said at least one valley is substantially complementary to a first region of said substrate and said at least one mesa is substantially complementary to a second region of said substrate.

41. A method as recited in claim 40, wherein said first region is a baseline level of said substrate and said second region is a recess in said substrate.

42. A method as recited in claim 40, wherein said first region is a pedestal over said substrate and said second region is a baseline level of said substrate.

43. A method as recited in claim 40, wherein a spacing between opaque elements disposed over said at least one mesa and said region is substantially equal to a spacing between opaque elements disposed in said at least one valley and said another region.

44. A method as recited in claim 43, wherein said irradiating is performed using electromagnetic radiation.

45. A method as recited in claim 39, wherein said locating said multi-level mask further comprises passively aligning said mask to said substrate.

46. A method as recited in claim 45, wherein said substrate includes recesses for receiving alignment fiducials disposed on said multi-level mask.

47. A method as recited in claim 45, wherein positioning member are disposed between said mask and said substrate.

48. A method as recited in claim 47, wherein said positioning members are microspheres.

49. A method of fabricating a multi-level mask, the method comprising:
providing a top flat mask and a bottom flat mask;
locating said top flat mask over said bottom flat mask; and
selectively etching said top flat mask to form at least one mesa and at least one valley.

50. A method as recited in claim 49, wherein said at least one valley is at a first level of the multi-level mask and said mesa is at a second level of the multi-level mask.

51. A method of fabricating a multi-level mask, the method comprising:
providing a base layer;
forming at least one mesa over said base layer;
forming at least one valley over said base layer; and
forming at least one opaque element on at least one of said mesas and forming at least one opaque element in at least one of said valleys.

52. A method as recited in claim 51, wherein said at least one mesa has a transmittance that is greater than or equal to a transmittance of said base layer.

53. A method as recited in claim 51, wherein said base layer and said at least one mesa are of a same material.

54. A method as recited in claim 51, wherein said base layer and said at least one mesa are of different materials.

55. An apparatus for providing backside mask alignment for a substrate, comprising:
A multi-level mask having a valley and a first mesa, and a
first alignment pattern on the first mesa; and
a mask having second alignment pattern opposed to the first mesa.

56. An apparatus as recited in claim 55, wherein the first mesa is disposed at a periphery of said multi-level mask

57. An apparatus as recited in claim 55, wherein the second mask is a multi-level mask having a second mesa and the second alignment pattern is disposed on the second mesa.

58. An apparatus as recited in claim 57, wherein a combined thickness of the first mesa and second mesa is within approximately −50 μm to approximately +50 μm of a thickness of said substrate.

59. An apparatus as recited in claim 55, wherein said mask is a flat mask and said firs mesa has a thickness within approximately −50 μm to approximately +50 μm of a thickness of the substrate.

60. A method for providing backside alignment, the method comprising:
(a.) providing a substrate;
(b.) disposing the substrate onto a valley of a multi-level mask, wherein the multi-level mask has a first mesa, and alignment patterns on the first mesa; and
(c.) aligning a mask to the alignment patterns on the first mesa, wherein the substrate is disposed between the multi-level mask and the mask.

61. A method as recited in claim 60, wherein the mask is a planar mask.

62. A method as recited in claim 60, wherein the first mesa has a thickness within approximately −10 μm to approximately +10 μm of a thickness of the substrate.

63. A method as recited in claim 60, wherein the mask is a multi-level mask, and the mask has a second mesa having alignment patterns.

64. A method as recited in claim 63, wherein a combined thickness of the first mesa and second mesa is within approximately −50 μm to approximately +50 μm of a thickness of the substrate.

65. A method as recited in claim 63, wherein a combined thickness of the first mesa and second mesa is within −10 μm to approximately +50 μm of a thickness of the substrate.

66. A multi-level mask as recited in claim 13, wherein said at least one mesa has sidewalls, and an opaque element substantially covers at least one of said sidewalls.
